(19) United States
(12) Patent Application Publication
(10) Pub. No.: US 2026/0090178 A1
(43) Pub. Date: Mar. 26, 2026

(54) METHOD FOR PREPARING MID-INFRARED FOCAL PLANE DETECTOR BASED ON Sn-DOPED PbSe QUANTUM DOTS

(71) Applicant: SUN YAT-SEN UNIVERSITY, Guangdong (CN)

(72) Inventors: Zhaohui LI, Guangdong (CN); Yifan CHEN, Guangdong (CN)

(73) Assignee: SUN YAT-SEN UNIVERSITY, Guangdong (CN)

(21) Appl. No.: 19/409,769

(22) Filed: Dec. 5, 2025

Related U.S. Application Data
(63) Continuation of application No. PCT/CN2024/104409, filed on Jul. 9, 2024.

(30) Foreign Application Priority Data
Apr. 9, 2024 (CN) 202410422689.0

(51) Int. Cl. H10K 30/15; B82Y 20/00; B82Y 40/00; C01B 19/00; C01G 21/21; C09K 11/88; H10K 30/40; H10K 71/12

(52) U.S. Cl. CPC H10K 30/152; C01B 19/002; C01G 21/21; C09K 11/881; H10K 30/40; H10K 71/12; B82Y 20/00; B82Y 40/00; C01P 2004/03; C01P 2006/60

(57) ABSTRACT

The present invention relates to the technical field of thermal imaging of mid-infrared focal plane detectors, and more particularly relates to a method for preparing a mid-infrared focal plane detector based on Sn-doped PbSe quantum dots. The mid-infrared focal plane detector is prepared on a readout integrated circuit (ROIC) substrate, and is composed of an Au bottom electrode, a PbS hole transport layer, a Sn-doped PbSe photosensitive layer, and a PIN heterojunction of a ZnO electron transport layer sequentially constructed by an ion beam sputtering method, a spin-coating method, a spin-coating method, and an ion beam sputtering method, respectively, and an indium tin oxide (ITO) top electrode finally evaporated by an ion beam sputtering method.

### CROSS-REFERENCE TO RELATED APPLICATION

This application is a continuation of international application of PCT application serial no. PCT/CN2024/104409, filed on Jul. 9, 2024, which claims the priority benefit of China application no. 202410422689.0, filed on Apr. 9, 2024. The entirety of each of the above-mentioned patent applications is hereby incorporated by reference herein and made a part of this specification.

### TECHNICAL FIELD

The present invention relates to the technical field of thermal imaging of mid-infrared focal plane detectors, and more particularly relates to a method for preparing a mid-infrared focal plane detector based on Sn-doped PbSe quantum dots.

### BACKGROUND ART

Up to now, infrared detectors have undergone development from the first generation to the fourth generation, and have been gradually developed from single-pixel detectors into focal plane detectors with large area arrays, miniaturized sizes, low costs, double colors, and multiple arrays. According to division by operating infrared wavelengths transmitted through atmospheric windows, the infrared detectors can be divided into near-infrared detectors (1 μm-3 μm), mid-infrared detectors (3 μm-5 μm), and far-infrared detectors (8 μm-10 μm). Additionally, according to different operating temperatures of the detectors, the infrared detectors can also be divided into cooled and uncooled detectors. The cooled detectors have been widely used due to their high detectivity and low signal-to-noise ratios, but have also been limited in further development due to their large volumes (Dewar flask packaging) and high energy consumption (circular cooling with liquid nitrogen). The uncooled detectors have been favored in the civilian market due to their chip-level dimensions and operating temperatures at room temperature, and can also be divided into thermal sensitive detectors and photon detectors according to different operating principles. The photon detectors have response speeds that are 1-2 orders of magnitude higher than the thermal sensitive detectors, thus having greater advantages in thermal imaging of focal plane arrays.

Currently, the uncooled photon infrared detectors at home and abroad have achieved breakthroughs and commercial applications in focal plane detector arrays in the near-infrared region (1-3 μm), including InGaAs detectors, GeSi detectors, PbS detectors, etc. In the mid-infrared region (3-5 μm), China is still at a stage of cooled focal plane detectors (including CdHgTe detectors, InSb detectors, and quantum well detectors). In recent years, foreign companies have researched and developed of chip-level uncooled PbSe thin-film mid- and far-infrared focal plane detectors. However, thermal noise of thin film bulk materials leads to higher dark currents in mid-infrared focal plane detectors, thereby decreasing the detectivity of the detectors.

In terms of preparation processes for infrared focal plane detectors, the detectors that have been commercialized currently are mainly prepared by using a flip chip packaging detector process and a direct thin film growth process on a readout integrated circuit (ROIC) substrate prepared by a Si complementary metal oxide semiconductor (CMOS) technology. The former is primarily achieved by enabling flip chip packaging of an indium column on a detector thin film and an indium column on the ROIC; and the latter utilizes thin film growth techniques such as metal-organic chemical vapor deposition (MOCVD) or molecular beam epitaxy (MBE) to directly grow a detector thin film on the ROIC. Both the processes are relatively complicated and have single functions, high requirements for equipment, high process costs, poor controllability, and large material dimensions.

### SUMMARY

To overcome the above deficiencies in the prior art, the present invention provides a method for preparing a mid-infrared focal plane detector based on Sn-doped PbSe quantum dots, which has a simple preparation process and effectively improves detection efficiency of the detector.

To address the above technical problems, technical solutions adopted by the present invention are as follows.

A method for preparing a mid-infrared focal plane detector based on Sn-doped PbSe quantum dots includes the following steps:
S1. depositing an Au array bottom electrode to serve as an array bottom electrode on an ROIC substrate by photolithography and an ion beam sputtering method;
S2. preparing a PbS quantum dot hole transport layer on the array bottom electrode by a spin-coating method;
S3. preparing a Sn-doped PbSe quantum dot photosensitive layer on the PbS quantum dot hole transport layer by a spin-coating method;
S4. preparing a PIN heterojunction of a ZnO electron transport layer on the Sn-doped PbSe quantum dot photosensitive layer by an ion beam sputtering method; and
S5. depositing an indium tin oxide (ITO) thin film to serve as a top electrode on the ZnO electron transport layer by an ion beam sputtering method to obtain the mid-infrared focal plane detector.

In the present invention, the mid-infrared focal plane detector is prepared on the ROIC substrate, and is composed of the Au bottom electrode, the PbS hole transport layer, the Sn-doped PbSe photosensitive layer, and the PIN heterojunction of the ZnO electron transport layer sequentially constructed by the ion beam sputtering method, the spin-coating method, the spin-coating method, and the ion beam sputtering method, respectively, and the ITO top electrode finally evaporated by the ion beam sputtering method.

According to the above technical means, the focal plane detector is prepared based on the Sn-doped PbSe quantum dots in the present invention. Compared with PbSe thin films, PbSe quantum dots have a smaller dimension, which can effectively suppress propagation of thermal noise. Since band gaps of the quantum dots are changed with variation of the dimension, photosensitive materials with different spectral responses are obtained. For a mid-infrared band, the PbSe quantum dots have a band gap of 4.7 μm. Thus, the PbSe quantum dots can achieve detection in the mid-infrared band. In summary, the Sn-doped PbSe quantum dots of the present invention have the advantage of high mid-infrared response, thereby achieving preparation of an uncooled PbSe mid-infrared focal plane detector with a low cost, chip integration, and a simple process.

In one of embodiments, the Sn-doped PbSe quantum dots and the PbS quantum dots are synthesized by a thermal injection method, where the Sn-doped PbSe quantum dots are subjected to surface modification treatment by applying a room temperature oxidation method and a liquid-phase iodination method after synthesis.

In one of embodiments, the step S2 includes:
S21. preparing a PbS quantum dot spin-coating solution;
S22. spin-coating the PbS quantum dot spin-coating solution onto the array bottom electrode to obtain a PbS quantum dot spin-coating layer;
S23. treating the PbS quantum dot spin-coating layer spin-coated on the array bottom electrode with an EDT-methanol solution to facilitate ligand exchange, followed by rinsing with methanol; and
S24. repeating the step S23 to enable a dimension of the PbS quantum dots to reach a set range, thus completing preparation of the PbS quantum dot hole transport layer.

In one of embodiments, the step S21 includes:
S211. mixing lead oxide with an octadecene (ODE) solution and an oleic acid (OA) solution to obtain a mixture, and heating the mixture to 140° C.-150° C. in a vacuum environment;
S212. adding a bisulfide solution diluted with the ODE solution into the mixture of the step S211 to carry out a reaction for a period of time to obtain a PbS reaction solution; and
S213. adding ethanol into the PbS reaction solution for centrifugation and precipitation to obtain PbS quantum dots, and re-dispersing the PbS quantum dots into an octane solution to obtain the PbS quantum dot spin-coating solution.

In one of embodiments, the step S211 specifically includes: weighing an appropriate amount of the lead oxide into a container A, then adding the ODE solution and the OA solution in an amount of 2-3 times the weight of the lead oxide into the container A, and heating the container A under vacuum at 100° C.-110° C. for a period of time until the temperature is raised to 140° C.-150° C.

In one of embodiments, the step S3 includes:
S31. preparing a dimethylformamide solution with dispersed Sn-doped PbSe quantum dot;
S32. spin-coating the dimethylformamide solution with dispersed Sn-doped PbSe quantum dot onto the PbS quantum dot spin-coating layer for a period of time, followed by washing with acetonitrile(i.e., subsequently washing the PbS quantum dot spin-coating layer with acetonitrile); and
S33. repeating the step S32 for at least two times to enable a dimension of the Sn-doped PbSe quantum dots to reach a set range, thus completing preparation of the Sn-doped PbSe quantum dot photosensitive layer.

In one of embodiments, the step S31 specifically includes:
S311. adding a lead acetate trihydrate, tin acetate, an oleic acid solution, a diphenyl ether solution, and a trioctylphosphine solution into a container B for mixing, and heating and drying the container B in a vacuum environment at 70° C.-90° C.;
S312. dissolving a selenium powder in a trioctylphosphine solution to form a trioctylphosphine selenide solution, and adding the resulting solution into the container B in an N₂ atmosphere to form a precursor solution;
S313. weighing and adding a diphenyl ether solution into a container C, performing drying the diphenyl ether solution under vacuum at 70° C.-90° C. for a period of time, and then continuously raising the temperature to 240° C.-250° C. in an N₂ atmosphere;
S314. rapidly adding all the precursor solution in the container B into the container C to carry out a reaction for a certain period of time, placing the container C into an ice water bath for quenching, and cooling the container C to room temperature to obtain a Pb₁₋ₓSnₓSe quantum dot reaction solution, where x=0-0.11;
S315. performing centrifugation to precipitate Pb₁₋ₓSnₓSe quantum dots from the Pb₁₋ₓSnₓSe quantum dot reaction solution with ethanol, and re-dispersing the quantum dots into a hexane solution; and performing centrifugation again to precipitate the Pb₁₋ₓSnₓSe quantum dots from the hexane solution with an ethanol solution to obtain the Pb₁₋ₓSnₓSe quantum dots, and placing the Pb₁₋ₓSnₓSe quantum dots at room temperature for drying and oxidation in a low oxygen concentration atmosphere;
S316. dispersing the Pb₁₋ₓSnₓSe quantum dots obtained in the step S315 into an octane solution to obtain a Pb₁₋ₓSnₓSe quantum dot-octane solution; dissolving lead iodide and ammonium acetate in a dimethylformamide solution, and adding the resulting solution into the Pb₁₋ₓSnₓSe quantum dot-octane solution at a volume ratio of 1:1; and performing mixing by vibration for a period of time until the Pb₁₋ₓSnₓSe quantum dots are transferred from the octane solution to the dimethylformamide solution to obtain a Pb₁₋ₓSnₓSe quantum dot dimethylformamide solution; and
S317. performing centrifugation and precipitation on the Pb₁₋ₓSnₓSe quantum dot dimethylformamide solution to obtain the Pb₁₋ₓSnₓSe quantum dots, rinsing the Pb₁₋ₓSnₓSe quantum dots with an octane solution to remove residual impurity ions, and then rinsing and dispersing the Pb₁₋ₓSnₓSe quantum dots into a dimethylformamide solution.

In one of embodiments, the step S311 includes: weighing the lead acetate (II) trihydrate and the tin acetate (II) into the container B, where a ratio of the lead acetate (II) trihydrate to the tin acetate (II) is 1:(0.5-1); then adding the oleic acid, the diphenyl ether, and the trioctylphosphine at a volume ratio of 1:1:1 into the container B; and heating and drying the container B in a vacuum environment at 70° C.-90° C.

In one of embodiments, the step S312 includes: dissolving 1.5-3 mmol of the selenium powder in the trioctylphosphine solution to form the trioctylphosphine selenide solution, and adding the trioctylphosphine selenide solution into the container B in an N₂ atmosphere to form the precursor solution.

In one of embodiments, the step S316 includes: dispersing the Pb₁₋ₓSnₓSe quantum dots in the octane solution to obtain the Pb₁₋ₓSnₓSe quantum dot-octane solution; dissolving the lead iodide and the ammonium acetate in 1 ml of the dimethylformamide solution, and adding the resulting solution into the Pb₁₋ₓSnₓSe quantum dot-octane solution at the volume ratio of 1:1; and vigorously shaking a mixed solution of the two for 1-2 minutes until the Pb₁₋ₓSnₓSe quantum dots are transferred from the octane solution to the dimethylformamide solution, then removing a supernatant, followed by rinsing with octane for several times to ensure complete transfer.

The dimensions of the PbS quantum dots and the Sn-doped PbSe quantum dots are determined according to a wavelength range required to be detected by the detector.

Compared with the prior art, the present invention has beneficial effects as follows: according to the method for preparing a mid-infrared focal plane detector based on Sn-doped PbSe quantum dots provided by the present invention, the Sn-doped PbSe quantum dots have the advantage of high mid-infrared response, and the method of the present invention can achieve preparation of an uncooled PbSe mid-infrared focal plane detector with a low cost, chip integration, and a simple process.

### BRIEF DESCRIPTION OF THE DRAWINGS

FIG. 1 shows a flow schematic diagram of a method of the present invention.

FIG. 2 shows a sectional view of a scanning electron microscopy image of a mid-infrared focal plane detector in the present invention.

FIG. 3 shows an actual device (64×64 pixel array) of the mid-infrared focal plane detector prepared by the method of the present invention.

### DESCRIPTION OF THE EMBODIMENTS

The technical solutions in the embodiments of the present invention are clearly and completely described below in conjunction with the accompanying drawings in the embodiments of the present invention. Obviously, the embodiments described are merely a part of the embodiments of the present invention, rather than all of the embodiments. The present invention is described below in one of the embodiments in conjunction with specific implementations. The accompanying drawings are provided for exemplary illustration only, representing only schematic diagrams rather than physical images, and should not be construed as limiting the present patent. To better illustrate the embodiments of the present invention, some components in the accompanying drawings may be omitted, enlarged, or reduced, which do not represent actual product sizes. For those skilled in the art, it is understandable that some known structures and descriptions thereof in the accompanying drawings may be omitted.

In the description of the present invention, it should be understood that terms, such as “up”, “down”, “left”, and “right”, indicating orientation or position relationships, are based on orientation or position relationships shown in the accompanying drawings, only to facilitate the description of the present invention and simplify the description, rather than to indicate or imply that a device or an element referred to needs to have a specific orientation or be constructed and operated in a specific orientation. Therefore, the terms describing the position relationships in the accompanying drawings are only used for exemplary illustration and should not be construed as limiting the present patent. For those of ordinary skill in the art, specific meanings of the above terms can be understood according to specific circumstances. Additionally, if the embodiments of the present invention involve descriptions, such as “first” and “second”, such descriptions, such as “first” and “second”, are solely for descriptive purposes and should not be construed as indicating or implying relative importance or implicitly specifying quantities of indicated technical features. Thus, features defined by “first” and “second” may expressly or implicitly include at least one of such features. Additionally, the meaning of “and/or” appearing in the context is to include three parallel solutions. For example, “A and/or B” includes a solution of A, a solution of B, or a solution where both A and B are satisfied simultaneously.

### Embodiment 1

This embodiment provides a method for synthesizing Sn-doped PbSe quantum dots (Pb₁₋ₓSnₓSe quantum dots), which specifically includes the following steps:
step 1: weighing 1.5-3 mmol of a lead acetate (II) trihydrate and 0.75-3 mmol of tin acetate (II) into a flask A, and then adding oleic acid, diphenyl ether, and trioctylphosphine into the flask A at a volume ratio of 1:1:1; and heating and drying the flask A under vacuum conditions at 70° C.-90° C. for 1 hour;
step 2: dissolving 1.5-3 mmol of a selenium powder in 1 mL-2 mL of trioctylphosphine to form a trioctylphosphine selenide solution, and adding the trioctylphosphine selenide solution into the flask A in an N₂ atmosphere to form a precursor solution;
step 3: weighing 1 mL of diphenyl ether into a flask B for drying under vacuum at 70° C.-90° C. for 1 hour, and continuously raising the temperature to 240° C.-250° C. in an N₂ atmosphere;
step 4: rapidly injecting all the precursor solution in the flask A into the flask B to carry out a reaction for 1 minute, then placing the flask B into an ice water bath for quenching, and performing cooling the flask B to room temperature;
step 5: performing centrifugation to precipitate Pb₁₋ₓSnₓSe (x=0-0.11) quantum dots from the reaction solution with ethanol (at a volume ratio of 2:1), and re-dispersing the quantum dots into hexane; performing re-precipitation operation again using the same method; and finally placing the Pb₁₋ₓSnₓSe quantum dots at room temperature for drying and oxidation in a low oxygen concentration (10 ppm) atmosphere for two days;
step 6: dispersing the Pb₁₋ₓSnₓSe quantum dots into a 15-25 mg/mL octane solution for liquid-phase iodination; dissolving 0.10 mol-0.2 mol of lead iodide and 0.04 mol-0.1 mol of ammonium acetate in 1 mL-2 mL of a dimethylformamide (DMF) solution, and adding the resulting solution into a Pb₁₋ₓSnₓSe quantum dot-octane solution obtained above at a volume ratio of 1:1; and vigorously shaking a mixed solution of the two for 1-2 minutes until the Pb₁₋ₓSnₓSe quantum dots are transferred from the octane to the DMF solution, then removing a supernatant, and performing rinsing with octane for several times (3-4 times) to ensure complete transfer; and
step 7: performing centrifugation and precipitation to obtain the Pb₁₋ₓSnₓSe quantum dots, performing rinsing with octane (3-4 times) to remove residual impurity ions, and re-dispersing the quantum dots into a DMF solution (1 mL-2 mL).

In step 5: the expression “performing centrifugation to precipitate Pb₁₋ₓSnₓSe (x=0-0.11) quantum dots from the reaction solution with ethanol (at a volume ratio of 2:1).” refers to performing centrifugation to precipitate Pb₁₋ₓSnₓSe (x=0-0.11) quantum dots from the reaction solution with ethanol and the volume ratio of the reaction solution to ethanol being 2:1.

### Embodiment 2

This embodiment provides a method for synthesizing PbS quantum dots, which includes the following steps:
step 1: weighing 0.3-1 g of lead oxide into a flask C, then adding 0.6 mL-2 mL of ODE and 0.6 mL-2 mL of OA into the flask C, and heating the flask C under vacuum at 100° C.-110° C. for a period of time until the temperature is raised to 140° C.-150° C.;
step 2: injecting a bis(trimethylsilyl) sulfide (1 mL) diluted with 10 mL of an ODE solution for a reaction for 4 minutes to obtain a PbS reaction solution; and
step 3: adding ethanol (at a volume ratio of 1:3) into the PbS reaction solution for centrifugation and precipitation to obtain the PbS quantum dots.

In step 3: the expression “adding ethanol (at a volume ratio of 1:3) into the PbS reaction solution for centrifugation and precipitation to obtain the PbS quantum dots” refers to adding ethanol into the PbS reaction solution for centrifugation and precipitation to obtain the PbS quantum dots and the volume ratio of the reaction solution to ethanol being 1:3.

### Embodiment 3

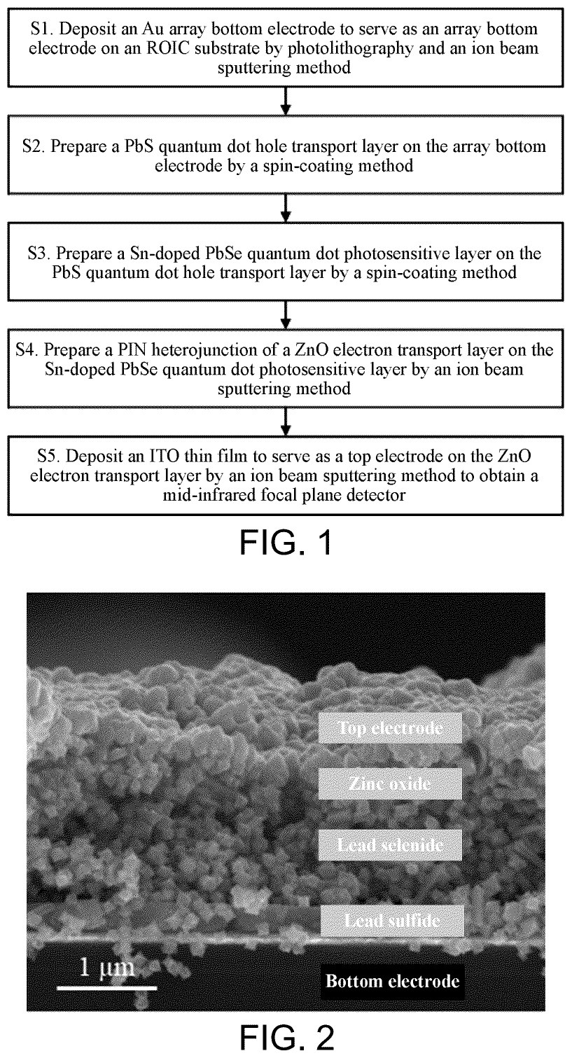

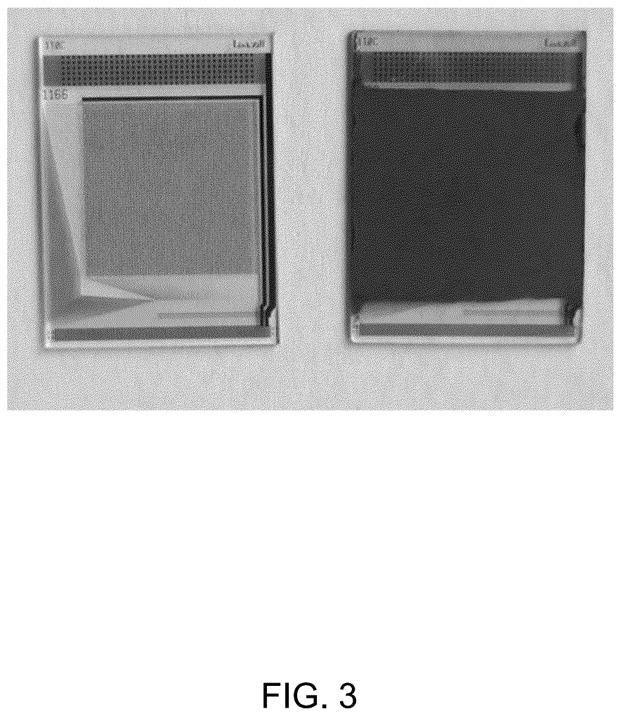

As shown in FIG. 1 and FIG. 2, this embodiment provides a method for preparing a mid-infrared focal plane detector based on Sn-doped PbSe quantum dots, which includes the following steps:
step 1: depositing an Au array bottom electrode (100 nm) to serve as an array bottom electrode on an ROIC substrate (64*64 pixel array) by photolithography and an ion beam sputtering method;
step 2: preparing a PbS quantum dot hole transport layer on the array bottom electrode by a spin-coating method;
S21. preparing a PbS quantum dot spin-coating solution using the PbS quantum dots prepared in Embodiment 2: dispersing the PbS quantum dots into a 25-35 mg/mL octane solution to obtain the PbS spin-coating solution;
S22. spin-coating the PbS quantum dot spin-coating solution onto the array bottom electrode at 2,000 r/min-3,000 r/min to obtain a PbS quantum dot spin-coating layer;
S23. treating the PbS quantum dot spin-coating layer spin-coated on the array bottom electrode with 0.1 mol of an EDT-methanol solution (1 mL) for at least 40 seconds to facilitate ligand exchange, followed by rinsing with methanol for at least 40 seconds(i.e., subsequently rinsing the PbS quantum dot spin-coating layer with acetonitrile); and
S24. repeating the step S23 to enable a dimension of the PbS quantum dots to reach 100 nm-300 nm, thus completing preparation of the PbS quantum dot hole transport layer;
step 3: preparing a Sn-doped PbSe quantum dot photosensitive layer on the PbS quantum dot hole transport layer by a spin-coating method;
S31. adopting a dimethylformamide solution with dispersed Sn-doped PbSe quantum dot prepared in Embodiment 1;
S32. spin-coating the dimethylformamide solution with dispersed Sn-doped PbSe quantum dot onto the PbS quantum dot spin-coating layer at 2,000 r.p.m.-3,000 r.p.m. for 40 seconds, followed by washing with acetonitrile (i.e., subsequently wash the PbS quantum dot spin-coating layer with acetonitrile); and
S33. repeating the step S32 for at least two times to enable a dimension of the Sn-doped PbSe quantum dots to reach 500 nm-2,000 nm, thus completing preparation of the Sn-doped PbSe quantum dot photosensitive layer;
step 4: preparing a ZnO electron transport layer with a thickeness of 200 nm-300 nm on the Sn-doped PbSe quantum dot photosensitive layer by an ion beam sputtering method; and
step 5: depositing an ITO thin film with a thickeness of 200 nm-800 nm to serve as a top electrode on the ZnO electron transport layer by an ion beam sputtering method to obtain the mid-infrared focal plane detector, as shown in FIG. 2 and FIG. 3.

In the present invention, the mid-infrared focal plane detector is prepared on the ROIC substrate, and is composed of the Au bottom electrode, the PbS hole transport layer, the Sn-doped PbSe photosensitive layer, and a PIN heterojunction of the ZnO electron transport layer sequentially constructed by the ion beam sputtering method, the spin-coating method, the spin-coating method, and the ion beam sputtering method, respectively, and the ITO top electrode finally evaporated by the ion beam sputtering method.

According to the above technical means, the focal plane detector is prepared based on the Sn-doped PbSe quantum dots in the present invention. Compared with PbSe thin films, PbSe quantum dots have a smaller dimension, which can effectively suppress propagation of thermal noise. Since band gaps of the quantum dots are changed with variation of the dimension, photosensitive materials with different spectral responses are obtained. For a mid-infrared band, the PbSe quantum dots have a band gap of 4.7 μm. Thus, the PbSe quantum dots can achieve detection in the mid-infrared band. In summary, the Sn-doped PbSe quantum dots of the present invention have the advantage of high mid-infrared response, thereby achieving preparation of an uncooled PbSe mid-infrared focal plane detector with a low cost, chip integration, and a simple process.

In the description of this specification, references to terms such as “one embodiment”, “some embodiments”, “example”, “specific example”, or “some examples” mean that specific features, structures, materials, or characteristics described in conjunction with the embodiment or example are included in at least one embodiment or example of the present invention. In this specification, illustrative expressions of the above terms do not necessarily refer to the same embodiment or example. Moreover, the specific features, structures, materials, or characteristics described may be combined in a suitable manner in any one or more embodiments or examples. Furthermore, in the case of no conflict, those skilled in the art may combine and integrate different embodiments or examples and features of different embodiments or examples described in this specification.

Obviously, the above embodiments of the present invention are merely examples provided to clearly illustrate the present invention and are not intended to limit the implementations of the present invention. For those of ordinary skill in the art, other modifications or variations in different forms may also be made based on the above description. It is neither necessary nor possible to enumerate all the implementations herein. Any modifications, equivalent substitutions, and improvements, etc., made within the spirit and principles of the present invention shall be included within the scope of protection defined by the claims of the present invention.

What is claimed is:

1. A method for preparing a mid-infrared focal plane detector based on Sn-doped PbSe quantum dots, comprising the following steps:
S1. depositing an Au array bottom electrode to serve as an array bottom electrode on a readout integrated circuit (ROIC) substrate by photolithography and an ion beam sputtering method;
S2. preparing a PbS quantum dot hole transport layer on the array bottom electrode by a spin-coating method;
S21. preparing a PbS quantum dot spin-coating solution: dispersing PbS quantum dots in a 25-35 mg/mL octane solution to obtain the PbS spin-coating solution;
S22. spin-coating the PbS quantum dot spin-coating solution onto the array bottom electrode at 2,000 r/min-3,000 r/min to obtain a PbS quantum dot spin-coating layer;
S23. treating the PbS quantum dot spin-coating layer spin-coated on the array bottom electrode with 0.1 mol of an Hydroxymethyl EDOT (EDT-methanol) solution for at least 40 seconds for ligand exchange, followed by rinsing with methanol for at least 40 seconds; and
S24. repeating the step S23 to enable a dimension of the PbS quantum dot spin-coating layer to reach 100 nm-300 nm, thus completing preparation of the PbS quantum dot hole transport layer;
S3. preparing a Sn-doped PbSe quantum dot photosensitive layer on the PbS quantum dot hole transport layer by a spin-coating method, specifically comprising:
S31. preparing a dimethylformamide solution with dispersed Sn-doped PbSe quantum dot;
S32. spin-coating the dimethylformamide solution with dispersed Sn-doped PbSe quantum dot onto the PbS quantum dot spin-coating layer for a period of time, followed by washing with acetonitrile; and
S33. repeating the step S32 for at least two times to enable a dimension of the Sn-doped PbSe quantum dot photosensitive layer to reach 500 nm-2,000 nm, thus completing preparation of the Sn-doped PbSe quantum dot photosensitive layer;
S4. preparing a PIN heterojunction of a ZnO electron transport layer at 200 nm-300 nm on the Sn-doped PbSe quantum dot photosensitive layer by an ion beam sputtering method; and
S5. depositing an indium tin oxide (ITO) thin film at 200 nm-800 nm to serve as a top electrode on the ZnO electron transport layer by an ion beam sputtering method to obtain the mid-infrared focal plane detector;
wherein the Sn-doped PbSe quantum dots and the PbS quantum dots are synthesized by a thermal injection method, wherein the Sn-doped PbSe quantum dots are subjected to surface modification treatment by applying a room temperature oxidation method and a liquid-phase iodination method after synthesis; and
the step S31 comprises:
S311. weighing 1.5-3 mmol of a lead acetate (II) trihydrate and 0.75-3 mmol of tin acetate (II) into a flask A, and then adding oleic acid, diphenyl ether, and trioctylphosphine into the flask A at a volume ratio of 1:1:1; and heating and drying the flask A under vacuum conditions at 70-90° C. for 1 hour;
S312. dissolving 1.5-3 mmol of a selenium powder in 1 mL-2 mL of trioctylphosphine to form a trioctylphosphine selenide solution, and adding the trioctylphosphine selenide solution into the flask A in an N₂ atmosphere to form a precursor solution;
S313. weighing 1 mL of diphenyl ether into a flask B for drying under vacuum at 70-90° C. for 1 hour, and continuously raising the temperature to 240-250° C. in an N₂ atmosphere;
S314. rapidly adding all the precursor solution in the flask A into the container B to carry out a reaction for 1 minute, placing the flask B into an ice water bath for quenching and performing cooling to room temperature to obtain a Pb₁₋ₓSnₓSe quantum dot reaction solution, wherein x equals 0 to 0.11;
S315. performing centrifugation to precipitate Pb₁₋ₓSnₓSe quantum dots from the Pb₁₋ₓSnₓSe quantum dot reaction solution with ethanol, and re-dispersing the Pb₁₋ₓSnₓSe quantum dots into a hexane solution; and performing centrifugation again to precipitate the Pb₁₋ₓSnₓSe quantum dots from the hexane solution with an ethanol solution to obtain the Pb₁₋ₓSnₓSe quantum dots, and placing the Pb₁₋ₓSnₓSe quantum dots at room temperature for drying and oxidation in a low oxygen concentration atmosphere;
S316. dispersing the Pb₁₋ₓSnₓSe quantum dots obtained in the step S35 into a 15 mg/mL-25 mg/mL octane solution for liquid-phase iodization to obtain a Pb₁₋ₓSnₓSe quantum dot-octane solution; dissolving 0.10 mol-0.2 mol of lead iodide and 0.04 mol-0.1 mol of ammonium acetate in 1 mL-2 mL of a dimethylformamide solution, and adding the resulting solution into the Pb₁₋ₓSnₓSe quantum dot-octane solution at a volume ratio of 1:1; and performing mixing by vibration for a period of time until the Pb₁₋ₓSnₓSe quantum dots are transferred from the octane solution to the dimethylformamide solution to obtain a Pb₁₋ₓSnₓSe quantum dot dimethylformamide solution; and
S317. performing centrifugation and precipitation on the Pb₁₋ₓSnₓSe quantum dot dimethylformamide solution to obtain the Pb₁₋ₓSnₓSe quantum dots, rinsing the Pb₁₋ₓSnₓSe quantum dots with an octane solution to remove residual impurity ions, and then rinsing and dispersing the Pb₁₋ₓSnₓSe quantum dots into a dimethylformamide solution.

2. The method for preparing the mid-infrared focal plane detector based on Sn-doped PbSe quantum dots according to claim 1, wherein the step S21 comprises:
S211. mixing lead oxide with an octadecene (ODE) solution and an oleic acid (OA) solution to obtain a mixture, and heating the mixture to 140° C.-150° C. in a vacuum environment;
S212. adding a bisulfide solution diluted with the ODE solution into the mixture of the step S211 to carry out a reaction for a period of time to obtain a PbS reaction solution; and
S213. adding ethanol into the PbS reaction solution for centrifugation and precipitation to obtain PbS quantum dots, and re-dispersing the PbS quantum dots into an octane solution to obtain the PbS quantum dot spin-coating solution.

3. The method for preparing the mid-infrared focal plane detector based on Sn-doped PbSe quantum dots according to claim 2, wherein the step S211 specifically comprises: weighing an appropriate amount of the lead oxide into a container A, then adding the ODE solution and the OA solution in an amount of 2-3 times the weight of the lead oxide into the container A, and heating the container A under vacuum at 100° C.-110° C. for a period of time until the temperature is raised to 140° C.-150° C.

4. The method for preparing the mid-infrared focal plane detector based on Sn-doped PbSe quantum dots according to claim 1, wherein dimensions of the PbS quantum dots and the Sn-doped PbSe quantum dots are determined according to a wavelength range required to be detected by the detector.

5. The method for preparing the mid-infrared focal plane detector based on Sn-doped PbSe quantum dots according to claim 2, wherein dimensions of the PbS quantum dots and the Sn-doped PbSe quantum dots are determined according to a wavelength range required to be detected by the detector.

6. The method for preparing the mid-infrared focal plane detector based on Sn-doped PbSe quantum dots according to claim 3, wherein dimensions of the PbS quantum dots and the Sn-doped PbSe quantum dots are determined according to a wavelength range required to be detected by the detector.
